(19) United States
(12) Patent Application Publication
(10) Pub. No.: US 2018/0207677 A1
(43) Pub. Date: Jul. 26, 2018

(54) VACUUM EVAPORATION APPARATUS

(71) Applicant: SHENZHEN CHINA STAR OPTOELECTRONICS TECHNOLOGY CO., LTD., Shenzhen City, Guangdong (CN)

(72) Inventor: Liang JIANG, Shenzhen City (CN)

(21) Appl. No.: 15/328,889

(22) PCT Filed: Dec. 19, 2016
(86) PCT No.: PCT/CN2016/110731

§ 371 Date: Jan. 24, 2017

(30) Foreign Application Priority Data
Oct. 14, 2016 (CN) 201610900262.2

(51) Int. Cl. B05C 17/08; H01L 51/56; C23C 14/04; C23C 14/24

(52) U.S. Cl. CPC B05C 17/08; C23C 14/24; C23C 14/042; H01L 51/56

(57) ABSTRACT

The invention provides a vacuum evaporation apparatus, wherein the magnetic plate comprises a plurality of magnetic units respectively corresponding to different areas of metal mask to attract the corresponding areas of metal mask to low surface of substrate by magnetic force, the driving mechanism comprises a plurality of driving units correspondingly one-to-one to magnetic units, and the magnetic units are driven by corresponding driving units to move upward/downward independently so that the stress generated during the mask sheet of metal mask attached to substrate is fully released by adjusting the movement order of magnetic units to reduce difficulty on metal mask design and improve yield rate. Moreover, the corresponding magnetic units are adjusted in real-time according to the color mixing situation of products to improve the equipment utilization rate, and the magnetic force on corresponding area of metal mask is independently adjusted according to product color mixing situation.

### BACKGROUND OF THE INVENTION

### 1. Field of the Invention

The present invention relates to the field of manufacturing organic light-emitting diode (OLED) display, and in particular to a vacuum evaporation apparatus.

### 2. The Related Arts

The organic light-emitting diode (OLED) display is a promising flat panel display technology, which provides excellent display performance, especially the properties of active light-emitting, simple structure, ultra-thin, quick response time, wide viewing angle, low power consumption and ability to realize flexible display, and is regarded as the “dream” display technology. In addition, the low production equipment investment, which is much smaller than the TFT-LCD, has won over the major display manufacturers, and has become the mainstream of the third-generation display technology. At present, OLED is at the stage of the eve before the mass production, and with the further research and new technologies continuing to emerge, OLED display will have a breakthrough development.

An OLED comprises an anode, an organic light-emitting layer, and a cathode sequentially formed on a substrate. In the OLED manufacturing process, the current technology for organic light-emitting layer patterning is still by using vacuum evaporation apparatus with metal mask in the vacuum evaporation process although there are many other alternatives. This is because the above approach can achieve good screen performance, and thus is widely adopted to pattern the organic light-emitting layer.

Wherein, the role of the metal mask is to make the OLED material deposited to the designated location; therefore, the locations, shapes and surface smoothness of the hole in the metal mask are very important. As shown in FIG. 1, the metal mask 10 usually comprises a mask frame 11 and a mask sheet 12 provided on the mask frame 11. The mask sheet 12 is formed with a plurality of mask sheet units 121 arranged with intervals, wherein each mask sheet unit 121 corresponds to the shape of an OLED product to be formed, with a plurality of holes uniformly distributed to define the pixels on the corresponding OLED product so that the vapor deposition material is deposited in the pixel area.

As shown in FIG. 2, the vacuum evaporation apparatus comprises: a vapor deposition chamber, and a cooling plate 21, a magnetic plate 22 and a driving mechanism 23 provided in the vapor deposition chamber. In the vapor deposition process, the metal mask 10 is used to define the pixels so that the evaporated organic material is deposited in the pixel areas. The cooling plate 21 is attached to one side of the substrate 30, and performs cooling on the metal mask 10 attached to the other side of the substrate 30 via the substrate 30. The magnetic plate 22 is provided on the cooling plate 21 and driven by the driving mechanism 23 to push down to attract the mask sheet 12 of the metal mask 10 to the side of the substrate 30 via the magnetic force. As such, the mask sheet 12 and the substrate 30 are brought into close contact to reduce the shadow effect during the vapor deposition process. In the prior art, since the magnetic plate 22 is pressed down as a whole, the middle and both end portions of the mask sheet 12 are simultaneously stressed so that the deformation of the mask sheet 12 cannot be completely released through the stress buffers at both ends. The unreleased deformation causes the mask sheet 12 to wrinkle, which in turn results in a decrease in the production yield rate due to color mixing.

### SUMMARY OF THE INVENTION

The object of the present invention is to provide a vacuum evaporation apparatus, with a magnetic plate comprising a plurality of corresponding magnetic plate units independently driven, able to effectively improve the color mixing caused by unreleased mask sheet deformation so as to improve the OLED production yield rate.

To achieve the above object, the present invention provides a vacuum evaporation apparatus, applied with a metal mask to perform vacuum evaporation on a substrate,

which comprises: a cooling plate, a magnetic plate and a driving mechanism for magnetic plate;

wherein the cooling plate being placed on the substrate to perform cooling on the metal mask and the substrate;

the magnetic plate being placed above the cooling plate for attracting the metal mask to a lower surface of the substrate via magnetic force of the magnetic plate;

the magnetic plate comprising a plurality of magnetic units corresponding respectively to a plurality of areas on the metal mask, the magnetic plate attracting the plurality of areas on the metal mask to the lower surface of the substrate via the magnetic force of the magnetic units;

the driving mechanism for magnetic plate comprising a plurality of driving units corresponding in one-to-one manner to the plurality of the magnetic units, the plurality of magnetic units moving upwards and downwards driven by the corresponding driving units independently.

According to a preferred embodiment of the present invention, the magnetic plate comprises three or more magnetic units.

According to a preferred embodiment of the present invention, the magnetic plate comprises three magnetic units arranged in parallel, wherein the magnetic unit in the middle is the center magnetic unit, the two magnetic units located at left and right sides of the center magnetic unit are side magnetic units;

when in use, the center magnetic unit and the side magnetic units are driven by the corresponding driving units to move downwards sequentially so that the center area of the metal mask corresponding to the center magnetic unit and two sides areas of the metal mask corresponding to the two side magnetic units are attracted to attach to the lower surface of the substrate sequentially via magnetic force.

According to a preferred embodiment of the present invention, each driving unit comprises a driving motor, and a driving shaft provided on a corresponding magnetic unit to allow the magnetic unit to rise and fall.

According to a preferred embodiment of the present invention, each magnetic unit comprises a filler, and a plurality of magnets surrounded by the filler.

According to a preferred embodiment of the present invention, the metal mask comprises a mask frame and a mask sheet provided on the mask frame, and the magnetic plate attracts the mask sheet of the metal mask to the lower surface of the substrate by the magnetic force.

According to a preferred embodiment of the present invention, the vacuum evaporation apparatus further comprises an evaporation chamber, and the cooling plate, the magnetic plate and the driving mechanism for the magnetic plate are all provided inside the evaporation chamber.

According to a preferred embodiment of the present invention, a substrate position adjusting unit and a substrate position observing unit are provided at the top of the evaporation chamber.

According to a preferred embodiment of the present invention, a vacuuming unit is provided at the side of the evaporation chamber.

According to a preferred embodiment of the present invention, an evaporation gas generation unit is provided at the bottom of the evaporation chamber.

The present invention also provides a vacuum evaporation apparatus, applied with a metal mask to perform vacuum evaporation on a substrate,

which comprises: a cooling plate, a magnetic plate and a driving mechanism for magnetic plate;

wherein the cooling plate being placed on the substrate to perform cooling on the metal mask and the substrate;

the magnetic plate being placed above the cooling plate for attracting the metal mask to a lower surface of the substrate via magnetic force of the magnetic plate;

the magnetic plate comprising a plurality of magnetic units corresponding respectively to a plurality of areas on the metal mask, the magnetic plate attracting the plurality of areas on the metal mask to the lower surface of the substrate via the magnetic force of the magnetic units;

the driving mechanism for magnetic plate comprising a plurality of driving units corresponding in one-to-one manner to the plurality of the magnetic units, the plurality of magnetic units moving upwards and downwards driven by the corresponding driving units independently;

wherein each driving unit comprising a driving motor, and a driving shaft provided on a corresponding magnetic unit to allow the magnetic unit to rise and fall;

wherein each magnetic unit comprising a filler, and a plurality of magnets surrounded by the filler.

Compared to the known techniques, the present invention provides the following advantages: the present invention provides a vacuum evaporation apparatus, comprising a cooling plate, a magnetic plate, and a driving mechanism for magnetic plate, applied with a metal mask to perform vacuum on a substrate. The magnetic plate is provided above the cooling plate to attract the metal mask to the lower surface of the substrate via the magnetic force, wherein the magnetic plate comprises a plurality of magnetic units respectively corresponding to the different areas of the metal mask, the driving mechanism for magnetic plate comprises a plurality of driving units corresponding in one-to-one manner to the magnetic units, and the magnetic units are driven by the corresponding driving units to move upward and downward independently so that the stress generated during the mask sheet of the metal mask attached to the substrate can be fully released by adjusting the movement order of the plurality of magnetic units so as to reduce the difficulty on metal mask design and improve yield rate. Moreover, the corresponding magnetic units can be adjusted in real time according to the color mixing situation of the products to improve the equipment utilization rate, and the magnetic force on corresponding area of the metal mask can be independently adjusted according to the color mixing situation of the product.

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort.

### BRIEF DESCRIPTION OF THE DRAWINGS

The following provides a detailed description, in combination with the drawings, to explain the benefits of the present invention. In the drawings:

FIG. 1 is a schematic view showing the known structure for metal mask;

FIG. 2 is a schematic view showing the known structure of vacuum evaporation apparatus;

FIG. 3 is a schematic view the structure of vacuum evaporation apparatus provided by an embodiment of the present invention.

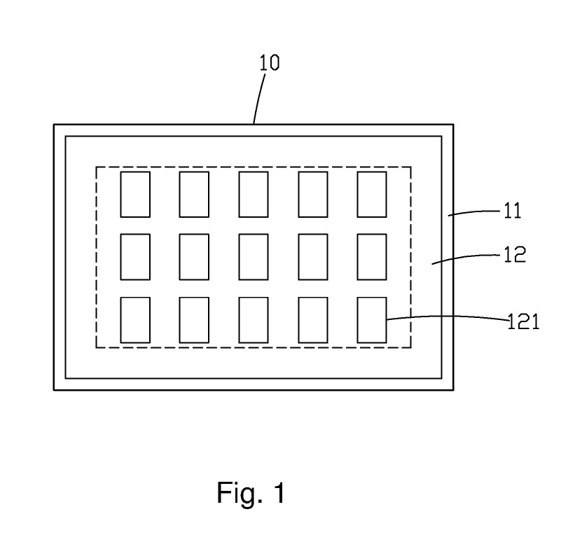

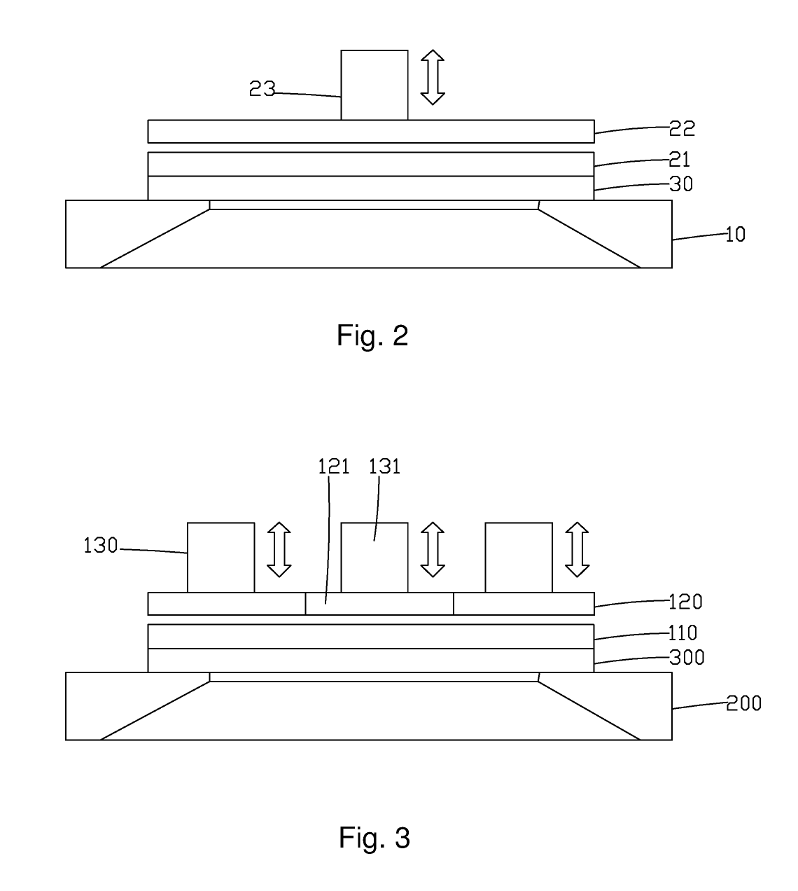

### DETAILED DESCRIPTION OF THE PREFERRED EMBODIMENTS

To further explain the technical means and effect of the present invention, the following refers to embodiments and drawings for detailed description.

Refer to FIG. 3. The present invention provides a vacuum evaporation apparatus, applied with a metal mask 200 to perform vacuum evaporation on a substrate 300.

The vacuum evaporation apparatus comprises: a cooling plate 110, a magnetic plate 120 and a driving mechanism 130 for magnetic plate.

The cooling plate 110 is placed on the substrate 300 to perform cooling on the metal mask 200 and the substrate 300.

The magnetic plate 120 is placed above the cooling plate 110 for attracting the metal mask 120 to a lower surface of the substrate 300 via magnetic force of the magnetic plate 120.

The magnetic plate 120 comprises a plurality of magnetic units 121 corresponding respectively to a plurality of areas on the metal mask 200, the magnetic plate 120 attracting the plurality of areas on the metal mask 200 to the lower surface of the substrate 300 via the magnetic force of the magnetic units 121; the driving mechanism 130 for magnetic plate comprising a plurality of driving units 131 corresponding in one-to-one manner to the plurality of the magnetic units 121, the plurality of magnetic units 121 moving upwards and downwards driven by the corresponding driving units 131 independently, so as to independently control the magnetic force on the corresponding areas of metal mask 200 by the plurality magnetic units 121.

Specifically, the metal mask 200 comprises a mask frame and a mask sheet provided on the mask frame, and the magnetic 120 is driven by the magnetic plate driving mechanism 130 to move downwards, and attracts the mask sheet, which is made of metal, towards the substrate 300 so that the mask sheet is attached to the lower surface of the substrate 300 by the magnetic force.

Specifically, the magnetic units 121 id driven by the corresponding driving units 131 to move downwards, and attracts the corresponding areas of the mask sheet towards the substrate 300 so that the corresponding areas of the mask sheet is attached to the lower surface of the substrate 300 by the magnetic force.

In the vacuum evaporation apparatus of the present invention, the magnetic plate 120 is provided as comprising a plurality of magnetic units 121 that can be independently controlled, so as to fully release, by adjusting the moving order of the plurality of magnetic units 121, the stress on the metal mask 200 generated during attracting the mask sheet of the metal mask 200 to the substrate 300, and reduce the design difficulty of the metal mask 200 and improve the production yield rate, as well as adjusting the magnetic force on the corresponding areas of the metal mask 200 by the corresponding magnetic unit 121 in accordance with the partial color mixing situation in the product. As such, the real-time adjustment of corresponding magnetic units 121 in accordance with the partial color mixing situation improves the equipment utilization rate.

Specifically, the magnetic plate 120 comprises three or more magnetic units 121.

Specifically, the magnetic plate 120 comprises three magnetic units 121 arranged in parallel, wherein the magnetic unit 121 in the middle is the center magnetic unit, the two magnetic units 121 located at left and right sides of the center magnetic unit are side magnetic units.

When in use, the center magnetic unit and the side magnetic units of the magnetic plate 120 are driven by the corresponding driving units 131 to move downwards sequentially so that the center area of the metal mask 200 corresponding to the center magnetic unit and two sides areas of the metal mask 200 corresponding to the two side magnetic units are attracted to attach to the lower surface of the substrate 300 sequentially via magnetic force. Compared to the known technique wherein the entire magnetic plate presses downwards so that the center and the two sides of the mask sheet are under force simultaneously to attach to the substrate, the present invention fully releases, by adjusting the moving order of the plurality of magnetic units 121, the stress on the metal mask 200 generated during attracting the mask sheet of the metal mask 200 to the substrate 300, and reduce the design difficulty of the metal mask 200 and improve the production yield rate.

Specifically, each driving unit 131 comprises a driving motor, and a driving shaft provided on a corresponding magnetic unit 121 to allow the magnetic unit to rise and fall.

Specifically, each magnetic unit 121 comprises a filler, and a plurality of magnets surrounded by the filler.

Specifically, the vacuum evaporation apparatus further comprises an evaporation chamber, and the cooling plate 110, the magnetic plate 120 and the driving mechanism 130 for the magnetic plate are all provided inside the evaporation chamber.

Specifically, a substrate position adjusting unit and a substrate position observing unit are provided at the top of the evaporation chamber to observe and adjust the position of the substrate 300 to realize the precise alignment with the metal mask 200.

Specifically, a vacuuming unit is provided at the side of the evaporation chamber to realize evaporation in a vacuum environment.

Specifically, an evaporation gas generation unit is provided at the bottom of the evaporation chamber to generate evaporation gas.

In summary, the present invention provides a vacuum evaporation apparatus, comprising a cooling plate, a magnetic plate, and a driving mechanism for magnetic plate, applied with a metal mask to perform vacuum on a substrate. The magnetic plate is provided above the cooling plate to attract the metal mask to the lower surface of the substrate via the magnetic force, wherein the magnetic plate comprises a plurality of magnetic units respectively corresponding to the different areas of the metal mask, the driving mechanism for magnetic plate comprises a plurality of driving units corresponding in one-to-one manner to the magnetic units, and the magnetic units are driven by the corresponding driving units to move upward and downward independently so that the stress generated during the mask sheet of the metal mask attached to the substrate can be fully released by adjusting the movement order of the plurality of magnetic units so as to reduce the difficulty on metal mask design and improve yield rate. Moreover, the corresponding magnetic units can be adjusted in real time according to the color mixing situation of the products to improve the equipment utilization rate, and the magnetic force on corresponding area of the metal mask can be independently adjusted according to the color mixing situation of the product.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A vacuum evaporation apparatus, applied with a metal mask to perform vacuum evaporation on a substrate;
which comprises: a cooling plate, a magnetic plate and a driving mechanism for magnetic plate;
wherein the cooling plate being placed on the substrate to perform cooling on the metal mask and the substrate;
the magnetic plate being placed above the cooling plate for attracting the metal mask to a lower surface of the substrate via magnetic force of the magnetic plate;
the magnetic plate comprising a plurality of magnetic units corresponding respectively to a plurality of areas on the metal mask, the magnetic plate attracting the plurality of areas on the metal mask to the lower surface of the substrate via the magnetic force of the magnetic units;
the driving mechanism for magnetic plate comprising a plurality of driving units corresponding in one-to-one manner to the plurality of the magnetic units, the plurality of magnetic units moving upwards and downwards driven by the corresponding driving units independently.

2. The vacuum evaporation apparatus as claimed in claim 1, wherein the magnetic plate comprises three or more magnetic units.

3. The vacuum evaporation apparatus as claimed in claim 2, wherein the magnetic plate comprises three magnetic units arranged in parallel, wherein the magnetic unit in the middle is the center magnetic unit, the two magnetic units located at left and right sides of the center magnetic unit are side magnetic units;
when in use, the center magnetic unit and the side magnetic units are driven by the corresponding driving units to move downwards sequentially so that the center area of the metal mask corresponding to the center magnetic unit and two sides areas of the metal mask corresponding to the two side magnetic units are attracted to attach to the lower surface of the substrate sequentially via magnetic force.

4. The vacuum evaporation apparatus as claimed in claim 1, wherein each driving unit comprises a driving motor, and a driving shaft provided on a corresponding magnetic unit to allow the magnetic unit to rise and fall.

5. The vacuum evaporation apparatus as claimed in claim 1, wherein each magnetic unit comprises a filler, and a plurality of magnets surrounded by the filler.

6. The vacuum evaporation apparatus as claimed in claim 1, wherein the metal mask comprises a mask frame and a mask sheet provided on the mask frame, and the magnetic plate attracts the mask sheet of the metal mask to the lower surface of the substrate by the magnetic force.

7. The vacuum evaporation apparatus as claimed in claim 1, wherein the vacuum evaporation apparatus further comprises an evaporation chamber, and the cooling plate, the magnetic plate and the driving mechanism for the magnetic plate are all provided inside the evaporation chamber.

8. The vacuum evaporation apparatus as claimed in claim 7, wherein a substrate position adjusting unit and a substrate position observing unit are provided at the top of the evaporation chamber.

9. The vacuum evaporation apparatus as claimed in claim 7, wherein a vacuuming unit is provided at the side of the evaporation chamber.

10. The vacuum evaporation apparatus as claimed in claim 7, wherein an evaporation gas generation unit is provided at the bottom of the evaporation chamber.

11. A vacuum evaporation apparatus, applied with a metal mask to perform vacuum evaporation on a substrate;
which comprises: a cooling plate, a magnetic plate and a driving mechanism for magnetic plate;
wherein the cooling plate being placed on the substrate to perform cooling on the metal mask and the substrate;
the magnetic plate being placed above the cooling plate for attracting the metal mask to a lower surface of the substrate via magnetic force of the magnetic plate;
the magnetic plate comprising a plurality of magnetic units corresponding respectively to a plurality of areas on the metal mask, the magnetic plate attracting the plurality of areas on the metal mask to the lower surface of the substrate via the magnetic force of the magnetic units;
the driving mechanism for magnetic plate comprising a plurality of driving units corresponding in one-to-one manner to the plurality of the magnetic units, the plurality of magnetic units moving upwards and downwards driven by the corresponding driving units independently;
wherein each driving unit comprising a driving motor, and a driving shaft provided on a corresponding magnetic unit to allow the magnetic unit to rise and fall;
each magnetic unit comprising a filler, and a plurality of magnets surrounded by the filler.

12. The vacuum evaporation apparatus as claimed in claim 11, wherein the magnetic plate comprises three or more magnetic units.

13. The vacuum evaporation apparatus as claimed in claim 12, wherein the magnetic plate comprises three magnetic units arranged in parallel, wherein the magnetic unit in the middle is the center magnetic unit, the two magnetic units located at left and right sides of the center magnetic unit are side magnetic units;
when in use, the center magnetic unit and the side magnetic units are driven by the corresponding driving units to move downwards sequentially so that the center area of the metal mask corresponding to the center magnetic unit and two sides areas of the metal mask corresponding to the two side magnetic units are attracted to attach to the lower surface of the substrate sequentially via magnetic force.

14. The vacuum evaporation apparatus as claimed in claim 11, wherein the metal mask comprises a mask frame and a mask sheet provided on the mask frame, and the magnetic plate attracts the mask sheet of the metal mask to the lower surface of the substrate by the magnetic force.

15. The vacuum evaporation apparatus as claimed in claim 11, wherein the vacuum evaporation apparatus further comprises an evaporation chamber, and the cooling plate, the magnetic plate and the driving mechanism for the magnetic plate are all provided inside the evaporation chamber.

16. The vacuum evaporation apparatus as claimed in claim 15, wherein a substrate position adjusting unit and a substrate position observing unit are provided at the top of the evaporation chamber.

17. The vacuum evaporation apparatus as claimed in claim 15, wherein a vacuuming unit is provided at the side of the evaporation chamber.

18. The vacuum evaporation apparatus as claimed in claim 15, wherein an evaporation gas generation unit is provided at the bottom of the evaporation chamber.
